(19) United States
(12) Patent Application Publication
(10) Pub. No.: US 2025/0366352 A1
(43) Pub. Date: Nov. 27, 2025

(54) DISPLAY DEVICE, ELECTRONIC DEVICE AND METHOD OF MANUFACTURING THE DISPLAY DEVICE

(71) Applicant: Samsung Display Co., LTD., Yongin-si (KR)

(72) Inventors: Eun Won SEO, Yongin-si (KR); Joon Ik LEE, Yongin-si (KR)

(21) Appl. No.: 19/084,713

(22) Filed: Mar. 19, 2025

(30) Foreign Application Priority Data
May 22, 2024 (KR) 10-2024-0066358

(51) Int. Cl. H10K 59/80; H10K 59/12; H10K 102/00

(52) U.S. Cl. CPC H10K 59/873; H10K 59/1201; H10K 2102/311

(57) ABSTRACT

A method of manufacturing a display device includes forming a display panel including a first area, a second area spaced apart from the first area in a first direction, and a bending area located between the first area and the second area, where the display panel includes a first surface and a second surface, which are opposite to each other, forming a base bending protection layer on the first surface of the display panel, forming a base support layer on the second surface of the display panel, forming a first bending protection layer by pre-curing the base bending protection layer, forming a second bending protection layer by pressing the first bending protection layer, and removing at least a portion of the base support layer. The base bending protection layer is formed before the removing the at least a portion of the base support layer.

This application claims priority to Korean Patent Application No. 10-2024-0066358, filed on May 22, 2024, and all the benefits accruing therefrom under 35 U.S.C. § 119, the content of which in its entirety is herein incorporated by reference.

### BACKGROUND

### 1. Field

The disclosure relates to a display device, electronic device and a method of manufacturing the display device.

### 2. Description of the Related Art

With the development of information technology, the importance of display devices, which are connection media between users and information, has been emphasized. Accordingly, research and development on display devices has been continuously conducted.

### SUMMARY

In a display device, at least a portion of the display device may be curved, and thus, visibility from various angles may be improved or the area of a non-display area (e.g., dead space) may be reduced. In a process of manufacturing such a display device, where at least a portion thereof is curved, methods to reduce dead space and minimize defects in the display device may be desired.

Embodiments of the disclosure provide a display device with reduced dead space and reduced defect rate, and a method of manufacturing the display device.

A method of manufacturing a display device in accordance with an embodiment of the disclosure includes forming a display panel including a first area, a second area spaced apart from the first area in a first direction, and a bending area located between the first area and the second area, where the display panel includes a first surface and a second surface, forming a base bending protection layer on the first surface of the display panel, forming a base support layer on the second surface of the display panel, forming a first bending protection layer by pre-curing the base bending protection layer, forming a second bending protection layer by pressing the first bending protection layer, and removing at least a portion of the base support layer, where the base bending protection layer may be formed before the removing the at least a portion of the base support layer.

In accordance with an embodiment, the forming the base support layer may include forming the base support layer to be in contact with the second surface of the display panel.

In accordance with an embodiment, the forming the base bending protection layer may include the forming the base bending protection layer to overlap the base support layer in a plan view.

In accordance with an embodiment, the forming the second bending protection layer may include pressing the first bending protection layer with a pressing part, and the pressing part may have a flat bottom surface which is substantially parallel to the first surface.

In accordance with an embodiment, the forming of the second bending protection layer may include pressing the first bending protection layer with a pressing part, the pressing part may include a first pressing part and a second pressing part, a bottom surface of the first pressing part may be an inclined surface with respect to the first surface, and a bottom surface of the second pressing part may be a flat surface which is substantially parallel to the first surface.

In accordance with an embodiment, the forming the second bending protection layer may include pressing the first bending protection layer with a pressing part, and a bottom surface of the pressing part may not be flat.

In accordance with an embodiment, the forming the second bending protection layer may include disposing pressing the first bending protection layer disposed to overlap the base support layer in a plan view.

In accordance with an embodiment, the forming the second bending protection layer may include pressing the first bending protection layer with a pressing part, a liner may be disposed below the pressing part in a way such that the liner is disposed between the first bending protection layer and the pressing part when the pressing part presses the first bending protection layer, and the liner may be a film.

In accordance with an embodiment, the forming the base bending protection layer on the first surface of the display panel may include applying a resin to have an area smaller than the bending area, and the resin may include a photocurable material or a thermosetting material.

In accordance with an embodiment, the method may further include forming a third bending protection layer by curing the second bending protection layer, where at least a portion of the third bending protection layer may be formed in a region outside a region where the display panel is disposed.

In accordance with an embodiment, the method may further include removing the at least a portion of the third bending protection layer, where the removing the at least a portion of the third bending protection layer may include cutting the third bending protection layer formed in the region outside the region where the display panel is disposed.

In accordance with an embodiment, a bending protection layer may be defined by a remaining portion of the third bending protection layer which remains after the removing the at least a portion of the third bending protection layer, and a contact area between the display panel and the base bending protection layer may be smaller than a contact area between the display panel and the bending protection layer.

In accordance with an embodiment, the bending protection layer may have a same shape as the display panel in the bending area.

In accordance with an embodiment, the forming the third bending protection layer may include exposing the second bending protection layer to heat or ultraviolet rays for less than about 5 minutes, and the forming the first bending protection layer may include exposing the base bending protection layer to the heat or the ultraviolet rays for less than about 3 minutes.

In accordance with an embodiment, the removing the at least a portion of the base support layer may include radiating a laser onto one region of the base support layer, the laser may be at least one selected from a CO₂ laser, a YAG laser, a nano second laser, a femto second laser, a Bessel beam, and a Gaussian beam, and the at least a portion of the base support layer to be removed may be a portion of the base support layer which overlaps the bending area in a plan view.

A display device in accordance with an embodiment of the disclosure includes a display panel including a first area, a second area spaced apart from the first area in a first direction, and a bending area located between the first area and the second area, where the display panel includes a first surface and a second surface, which are opposite to each other, a bending protection layer disposed in the bending area on the first surface of the display panel, and a support layer disposed in the first area and the second area on the second surface of the display panel, where the bending protection layer may have a thickness in a range of about 30 micrometers (μm) to about 120 μm, and the support layer may not overlap the bending area in a plan view.

In accordance with an embodiment, the bending protection layer may have a flat top surface which is substantially parallel to the first surface, and the top surface of the bending protection layer may be a surface opposite to a surface of the bending protection layer facing the display panel.

In accordance with an embodiment, the display device may further include a polarizing layer disposed in the first area on the first surface of the display panel, where the bending protection layer may include a first portion and a second portion, the first portion may have a thickness which decreases as a distance from the polarizing layer increases, and the second portion may have a uniform thickness.

In accordance with an embodiment, the display device may further include a polarizing layer disposed in the first area on the first surface of the display panel, where the bending protection layer may have a thickness which decreases as a distance from the polarizing layer increases.

In accordance with an embodiment, the bending protection layer may have a same shape as the display panel in the bending area.

An electronic device includes a processor to provide input image data; and a display device to display an image based on the input image data. The display device includes a display panel including a first area, a second area spaced apart from the first area in a first direction, and a bending area located between the first area and the second area, wherein the display panel includes a first surface and a second surface, which are opposite to each other; a bending protection layer disposed in the bending area on the first surface of the display panel; and a support layer disposed in the first area and the second area on the second surface of the display panel. The bending protection layer has a thickness in a range of about 30 μm to about 120 μm, and the support layer does not overlap the bending area in a plan view.

### BRIEF DESCRIPTION OF THE DRAWINGS

FIG. 1 is a schematic plan view of a display device in accordance with an embodiment.

FIG. 2 is a schematic cross-sectional view taken along line A-A′ of FIG. 1 in accordance with an embodiment.

FIG. 3 is a schematic cross-sectional view of a display panel in accordance with an embodiment.

FIG. 4 is a schematic cross-sectional view of a display device taken along line B-B′ of FIG. 1 in accordance with an embodiment.

FIG. 5 is a schematic cross-sectional view of a display device taken along line B-B′ of FIG. 1 in accordance with another embodiment.

FIG. 6 is a schematic cross-sectional view of a display device taken along line B-B′ of FIG. 1 in accordance with another embodiment.

FIG. 7 is a schematic flowchart of a method of manufacturing a display device in accordance with an embodiment.

FIGS. 8 to 15 are schematic diagrams of processes in an embodiment of a method of manufacturing the display device of FIG. 4.

FIG. 16 is a schematic diagram of a process in in an embodiment of a method of manufacturing the display device of FIG. 5.

FIG. 17 is a schematic diagram of a process in in an embodiment of a method of manufacturing the display device of FIG. 6.

FIG. 18 is a schematic block diagram illustrating an electronic device 1000 including a display device in accordance with an embodiment.

FIG. 19 is a schematic diagram illustrating an example where the electronic device 1000 of FIG. 18 is a smartphone.

FIG. 20 is a schematic diagram illustrating an example where the electronic device 1000 of FIG. 18 is a tablet computer.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device and a method of manufacturing the display device in accordance with embodiments will be described with reference to the accompanying drawings.

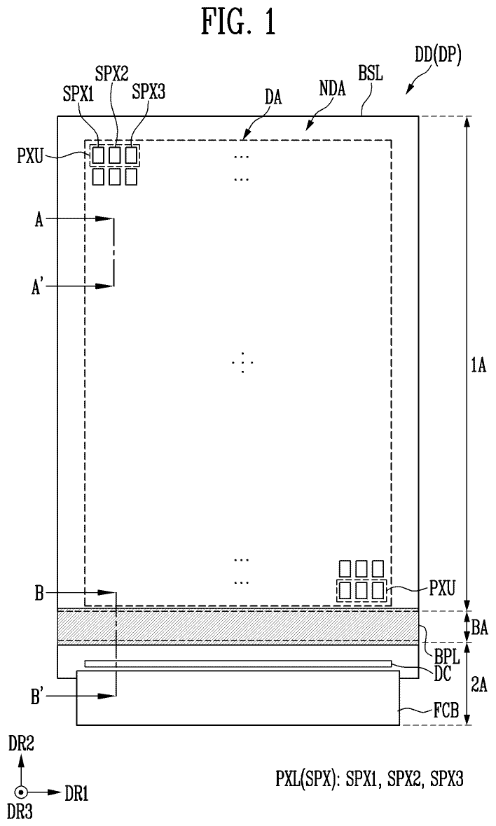

First, embodiments of a display device DD will be described with reference to FIGS. 1 to 6. FIG. 1 is a schematic plan view of a display device in accordance with an embodiment.

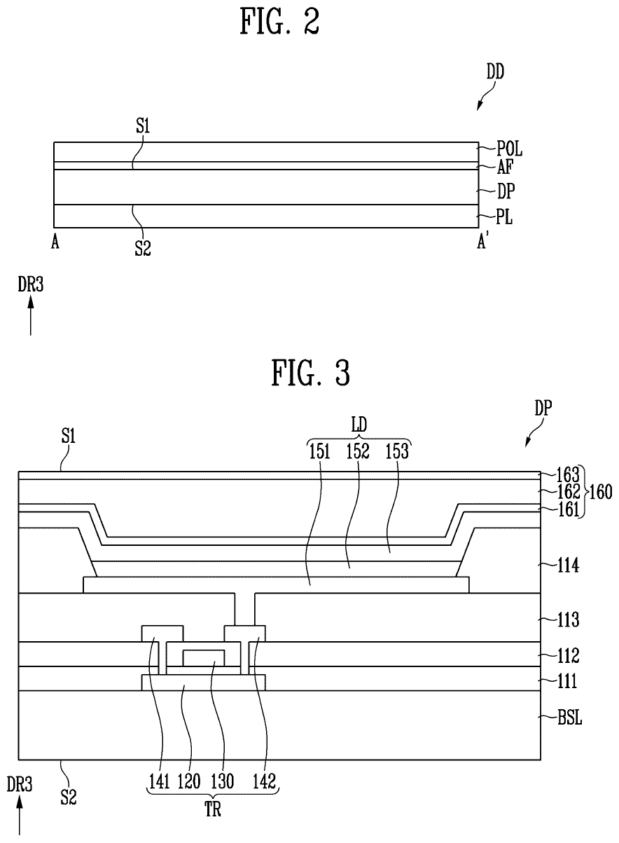

Referring to FIG. 1, an embodiment of the display device DD is configured to emit light. The display device DD may include a light emitting element (see LD of FIG. 3) and may include a display panel (see DP of FIG. 2) that displays a video (or an image). In accordance with an embodiment, the display device DD may be a device that displays moving images or still images. The display device DD may function or be used as display screen for portable electronic devices, such as mobile phones, smartphones, tablet personal computers (PCs), smart watches, watch phones, mobile communication terminals, electronic organizers, e-books, portable multimedia players (PMPs), navigation systems, and ultra mobile PCs (UMPCs). Also, the display device DD may be used as display screens for various products, such as televisions, laptops, monitors, billboards, and Internet of things (IoT) devices. However, the application field of the display device DD is not limited to specific examples.

In an embodiment, the display device DD may be formed as a rectangular plane having a short side in a first direction DR1 and a long side in a second direction DR2 crossing the first direction DR1. In an embodiment, corners at which the short side in the first direction DR1 meets the long side in the second direction DR2 may be round to have a certain curvature, or may be at a right angle. The planar shape of the display device DD is not limited to the rectangular shape and may be other round shapes, such as a polygonal shape, a circular shape, or an elliptical shape. The display device DD may be formed to be flat, but is not limited thereto. In another embodiment, for example, the display device DD may include a curved portion at an end thereof and having a constant curvature or a changing curvature.

In the disclosure, the first direction DR1 may be a “horizontal” direction that is a row direction of a pixel PXL. The second direction DR2 may be a column direction of the pixel PXL. The second direction DR2 may be perpendicular to the first direction DR1. A third direction DR3 may be a display direction of the display device DD or a normal direction of a plane on which a base layer BSL is disposed. The third direction DR3 may be a thickness direction of the display device DD or the base layer BSL.

The display device DD may include a display area DA and a non-display area NDA. The non-display area NDA may refer to an area other than the display area DA. The non-display area NDA may surround at least a portion of the display area DA.

The display area DA may refer to an area where the pixel PXL is disposed. The non-display area NDA may refer to an area where the pixel PXL is not disposed. A flexible circuit board FCB including a driving circuit chip DC connected to the pixel PXL of the display area DA, lines, and a pad portion where pads are disposed may be disposed in the non-display area NDA. The flexible circuit board FCB may be connected (or electrically connected) to a portion of the display panel DP in one area of the display panel DP through a conductive adhesive layer disposed on the display panel DP, so that driving signals may be generated in the display panel DP and applied to the pixels PXL.

The display device DD (or the display panel DP) may have a first area 1A, a second area 2A, and a bending area BA. In an embodiment, for example, the first area 1A may include the display area DA, and the second area 2A may be the non-display area NDA.

In an embodiment, the second area 2A may be disposed on one side of the first area 1A and may be spaced apart from the first area 1A in one direction. In an embodiment, for example, the second area 2A may be spaced apart from the first area 1A in a direction opposite to the second direction DR2.

The bending area BA may be located between the first area 1A and the second area 2A. The bending area BA may be bent along a bending axis extending in the first direction DR1 crossing the second direction DR2. The bending area BA may be an area where the display device DD (or the display panel DP) is bendable. The display device DD may be flexibly formed to be twistable, bendable, foldable, or rollable.

The driving circuit chip DC may be disposed in the second area 2A on the display panel DP. The flexible circuit board FCB may be disposed at an end portion of the second area 2A (e.g., an end portion on a side opposite to the second direction DR2) on the display panel DP. The flexible circuit board FCB may be spaced apart from the driving circuit chip DC in the second direction DR2. However, the disclosure is not limited thereto. In accordance with an embodiment, the driving circuit chip DC may be disposed on the flexible circuit board FCB.

The driving circuit chip DC and the flexible circuit board FCB may provide a driving signal to the display panel DP. The driving signal may refer to various signals for driving the display panel DP, such as a driving voltage, a gate signal, and a data signal.

In an embodiment, the display device DD may further include a bending protection layer BPL. The bending protection layer BPL may be disposed on the display panel DP. The bending protection layer BPL may cover the bending area BA on the top surface of the display panel DP. In an embodiment, the bending protection layer BPL may cover a portion of the first area 1A, the bending area BA, and a portion of the second area 2A.

The bending protection layer BPL may correspond to the shape of the display panel DP in the bending area BA. In an embodiment, for example, the bending protection layer BPL may have a same shape as the display panel DP in the bending area BA. In an embodiment, for example, where the display panel DP in the bending area BA has a rectangular shape, the bending protection layer BPL may have a rectangular shape. In an embodiment, for example, where the display panel DP in the bending area BA has a trapezoidal shape, the bending protection layer BPL may have a trapezoidal shape.

The bending protection layer BPL may be bendable together with the display panel DP in the bending area BA. The bending protection layer BPL may protect the display panel DP from external impact and minimize bending stress by controlling stress of the display panel DP when the display panel DP is bent.

In accordance with an embodiment, the pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel unit PXU capable of emitting light of various colors. Although FIG. 1 illustrates an embodiment where each of the pixels PXL includes three sub-pixels SPX1, SPX2, and SPX3, that is, the first sub-pixel SPX1, the second sub-pixel SPX2, and the third sub-pixel SPX3, embodiments of the disclosure are not limited thereto.

In accordance with an embodiment, the pixels PXL (or sub-pixels SPX) may be disposed to have a stripe or PENTILE™ arrangement structure. However, the disclosure is not necessarily limited thereto.

The first sub-pixel SPX1 may emit first light, the second sub-pixel SPX2 may emit second light, and the third sub-pixel SPX3 may emit third light. Here, the first light may be light in a red wavelength band, the second light may be light in a green wavelength band, and the third light may be light in a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm, but embodiments of the disclosure are not limited thereto.

Each of the first sub-pixel SPX1, the second sub-pixel SPX2, and the third sub-pixel SPX3 may be a light emitting element that emits light, and may include an inorganic light emitting diode including an inorganic semiconductor or an organic light emitting diode (OLED). However, the disclosure is not limited to a particular example, but embodiments in which the display device DD includes an OLED will be mainly described for convenience of description.

FIG. 2 is a schematic cross-sectional view taken along line A-A′ of FIG. 1 in accordance with an embodiment. FIG. 3 is a schematic cross-sectional view of the display panel in accordance with an embodiment.

Referring to FIGS. 2 and 3, an embodiment of the display device DD may include a display panel DP including a first surface S1 and a second surface S2. The display panel DP may display (or generate and output) an image. The display panel DP may include a plurality of pixels PXL for generating an image. In an embodiment, the display panel DP may provide the generated image in a direction in which the first surface S1 of the display panel DP faces. In such an embodiment, the first surface S1 of the display panel DP may be the surface of the display panel DP on which the image is displayed and may be the front surface of the display panel DP. In such an embodiment, the second surface S2 of the display panel DP may be opposite to the surface of the display panel DP on which the image is displayed, and may be the back surface of the display panel DP.

In an embodiment, as shown in FIG. 3, the display panel DP may include a base layer BSL, a transistor TR, a light emitting element LD, and an encapsulation layer 160.

The base layer BSL may be a flexible and insulating substrate. In an embodiment, for example, the base layer BSL may be a transparent resin substrate. In an embodiment, for example, the base layer BSL may be a polyimide (PI) substrate. However, the disclosure is not limited thereto.

An active layer 120 of the transistor TR may be disposed on the base layer BSL. The active layer 120 may include an oxide semiconductor, a silicon semiconductor, and an organic semiconductor. In an embodiment, for example, the oxide semiconductor may include an oxide of at least one selected from indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, etc. The active layer 120 may include a source region, a drain region, and a channel region located between the source region and the drain region.

In an embodiment, although not illustrated, a buffer layer may be disposed between the base layer BSL and the active layer 120. The buffer layer may prevent impurities in the base layer BSL from diffusing into the active layer 120. The buffer layer may include an inorganic insulating material, such as a silicon compound or metal oxide. In an embodiment, for example, the inorganic insulating material may include at least one selected from silicon oxide (SiₓO_{y}), silicon nitride (SiₓN_{y}), silicon oxynitride (SiₓO_{y}N_{z}), silicon oxycarbide (SiₓO_{y}C_{z}), silicon carbonitride (SiₓC_{y}N_{z}), aluminum oxide (AlₓO_{y}), aluminum nitride (AlₓN_{y}), tantalum oxide (TaₓO_{y}), hafnium oxide (HfₓO_{y}), zirconium oxide (ZrₓO_{y}), and titanium oxide (TiₓO_{y}). The buffer layer may have a single-layer structure or a multilayer structure including a plurality of insulating layers.

A first insulating layer 111 may be disposed on the active layer 120. The first insulating layer 111 may cover the active layer 120 on the base layer BSL. The first insulating layer 111 may include an inorganic insulating material, such as silicon oxide or metal oxide. The first insulating layer 111 may have a single-layer structure or a multilayer structure including a plurality of insulating layers.

A gate electrode 130 of the transistor TR may be disposed on the first insulating layer 111. The gate electrode 130 may overlap the channel region of the active layer 120. The gate electrode 130 may include a conductive material, such as metal, alloy, conductive metal nitride, conductive metal oxide, and transparent conductive material. In an embodiment, for example, the conductive material may include at least one selected from gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), aluminum (Al), aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), Tin oxide (SnO), indium oxide (InO), gallium oxide (GaO), indium zinc oxide (IZO) or a combination (e.g., an alloy) thereof. The gate electrode 130 may have a single-layer structure or a multilayer structure including a plurality of conductive layers.

A second insulating layer 112 may be disposed on the gate electrode 130. The second insulating layer 112 may cover the gate electrode 130 on the first insulating layer 111. The second insulating layer 112 may include an inorganic insulating material, such as silicon oxide or metal oxide. The second insulating layer 112 may have a single-layer structure or a multilayer structure including a plurality of insulating layers.

A source electrode 141 and a drain electrode 142 of the transistor TR may be disposed on the second insulating layer 112. The source electrode 141 and the drain electrode 142 may be connected to the source region and drain region of the active layer 120, respectively, through a hole defined or formed through the first and second insulating layers 111 and 112. Each of the source electrode 141 and the drain electrode 142 may include a conductive material, such as metal, alloy, conductive metal nitride, conductive metal oxide, and transparent conductive material. Each of the source electrode 141 and the drain electrode 142 may have a single-layer structure or a multilayer structure including a plurality of conductive layers.

The active layer 120, the gate electrode 130, the source electrode 141, and the drain electrode 142 may form the transistor TR.

A third insulating layer 113 may be disposed on the source electrode 141 and the drain electrode 142. The third insulating layer 113 may include an organic insulating material. In an embodiment, for example, the organic insulating material may include at least one selected from acryl resin, epoxy resin, phenol resin, polyamide resin, polyimide resin, and benzocyclobutene (BCB). The third insulating layer 113 may have a multilayer structure including one or more organic insulating layers and one or more inorganic insulating layers.

A first electrode 151 of the light emitting element LD may be disposed on the third insulating layer 113. The first electrode 151 may be connected to the source electrode 141 or the drain electrode 142. The first electrode 151 may include a conductive material, such as metal, alloy, conductive metal oxide, conductive metal nitride, and transparent conductive material. The first electrode 151 may have a single-layer structure or a multilayer structure including a plurality of conductive layers.

A fourth insulating layer 114 may be disposed on the first electrode 151. The fourth insulating layer 114 may cover the peripheral portion of the first electrode 151 and may defined or be provided with a pixel opening exposing the central portion of the first electrode 151. The fourth insulating layer 114 may include an organic insulating material.

An emission layer 152 of the light emitting element LD may be disposed on the first electrode 151. The emission layer 152 may be disposed within the pixel opening of the fourth insulating layer 114.

A second electrode 153 of the light emitting element LD may be disposed on the emission layer 152. The second electrode 153 may also be disposed on the fourth insulating layer 114. The second electrode 153 may include a conductive material, such as metal, alloy, conductive metal oxide, conductive metal nitride, or transparent conductive material. The second electrode 153 may have a single-layer structure or a multilayer structure including a plurality of conductive layers.

The first electrode 151, the emission layer 152, and the second electrode 153 may form the light emitting element LD.

The encapsulation layer 160 may be disposed on the second electrode 153. The encapsulation layer 160 may include at least one inorganic encapsulation layer and at least one organic encapsulation layer. In an embodiment, the encapsulation layer 160 may include a first inorganic encapsulation layer 161 disposed on the second electrode 153, an organic encapsulation layer 162 disposed on the first inorganic encapsulation layer 161, and a second inorganic encapsulation layer 163 disposed on the organic encapsulation layer 162.

In an embodiment, as shown in FIG. 2, the display device DD may further include an adhesive layer AF, a polarizing layer POL, and a support layer PL.

The polarizing layer POL may be disposed on the first surface S1 of the display panel DP. The polarizing layer POL may reduce external light reflection of the display device DD. In an embodiment, for example, when external light passes through the polarizing layer POL, is reflected from the bottom of the polarizing layer POL (e.g., from the display panel DP), and then passes through the polarizing layer POL again, the phase of the external light may change as the external light passes through the polarizing layer POL twice. Accordingly, the phase of the reflected light may be different from the phase of the incident light entering the polarizing layer POL, which may cause destructive interference. As external light reflection is reduced, the visibility of the display device DD may be improved.

The adhesive layer AF may be disposed between the display panel DP and the polarizing layer POL. The adhesive layer AF may attach the polarizing layer POL to the top surface (e.g., the first surface S1) of the display panel DP. In an embodiment, for example, the adhesive layer AF may include pressure sensitive adhesive (PSA), optical clear resin (OCR), or optical clear adhesive (OCA), including at least one selected from acryl-based adhesives, silicon-based adhesives, urethane-based adhesives, and rubber-based adhesives, and vinyl ether-based adhesives.

The support layer PL may be disposed below the display panel DP. In an embodiment, for example, the support layer PL may be disposed on the second surface S2 of the display panel DP. The support layer PL may be partially disposed below (e.g., disposed to cover only a portion of the second surface S2 of) the display panel DP. In an embodiment, for example, the support layer PL may expose a portion of the display panel DP in the bending area BA.

The support layer PL may increase resistance to compressive force due to external pressure. In an embodiment, for example, the support layer PL may serve to prevent deformation of the display panel DP. The support layer PL may be disposed on the rear surface of the display panel DP to support the display panel DP. The support layer PL may protect the display panel DP by absorbing impact applied from the outside or blocking infiltration of foreign materials (e.g., moisture) into the display panel DP.

The support layer PL may be disposed below the display panel DP to protect the display panel DP during the process of manufacturing the display device DD. The support layer PL may be a film layer. However, the disclosure is not limited thereto.

In accordance with an embodiment, although not shown in the drawings, the display device DD may further include a cover member or the like for protecting the top surface of the display device DD.

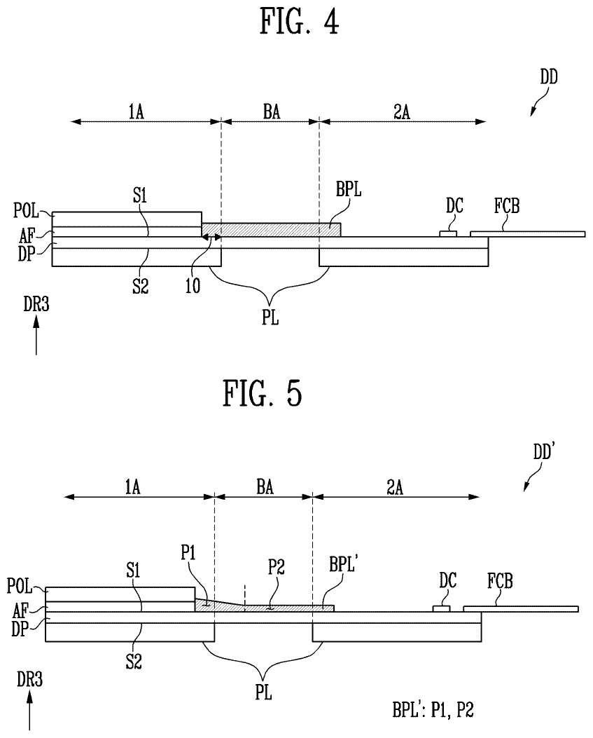

FIG. 4 is a schematic cross-sectional view of the display device taken along line B-B′ of FIG. 1 in accordance with an embodiment. FIG. 4 illustrates an embodiment before the display device DD is bent in the bending area BA, that is, an embodiment of the display device DD in an unbent state.

Referring to FIG. 4, in an embodiment, the polarizing layer POL and the adhesive layer AF may be disposed in the first area 1A on the display panel DP. In a plan view (or when viewed in the third direction DR3), the polarizing layer POL and the adhesive layer AF may overlap the first area 1A. In a plan view, the polarizing layer POL and the adhesive layer AF may not overlap the bending area BA.

The bending protection layer BPL may be disposed in the bending area BA on the display panel DP. In a plan view, the bending protection layer BPL may overlap the bending area BA. In accordance with an embodiment, the bending protection layer BPL may have a structure further extending from the bending area BA to the first area 1A and the second area 2A. In accordance with an embodiment, in a plan view, the bending protection layer BPL may overlap a portion of the first area 1A and a portion of the second area 2A.

The bending protection layer BPL may protect the bending area BA of the display panel DP. In an embodiment, for example, the bending protection layer BPL may protect a conductive layer in the bending area BA of the display panel DP. In an embodiment, for example, lines configured to transmit driving signals to the display panel DP may be disposed on the conductive layer in the bending area BA of the display panel DP. By adjusting the thickness and modulus of the bending protection layer BPL, the position of a stress neutral plane in a laminate including the display panel DP and the bending protection layer BPL may be adjusted. In an embodiment, for example, tensile stress applied to the conductive layer in the bending area BA of the display panel DP may be minimized through the bending protection layer BPL.

The bending protection layer BPL may cover at least a portion of a side surface of the polarizing layer POL and a side surface of the adhesive layer AF. The bending protection layer BPL may have a structure extending along the first direction DR1 to cover at least a portion of the side surfaces of the polarizing layer POL and the adhesive layer AF. The bending protection layer BPL may be in contact with at least a portion of the side surfaces of the polarizing layer POL and the adhesive layer AF. The side surfaces of the polarizing layer POL and the adhesive layer AF in contact with the bending protection layer BPL are perpendicular to the plane on which the display panel DP is disposed, and may be surfaces disposed closer to the bending area BA among the surfaces of the polarizing layer POL and the adhesive layer AF extending in the first direction DR1.

The bending protection layer BPL may not cover the top surface of the polarizing layer POL. In an embodiment, for example, in a plan view, the bending protection layer BPL may not overlap the polarizing layer POL. The top surface of the polarizing layer POL may be a surface opposite to the surface in contact with the adhesive layer AF.

In an embodiment, as shown in FIG. 4, the bending protection layer BPL may have an approximately flat surface. In an embodiment, for example, the bending protection layer BPL may have an approximately flat top surface. The top surface of the bending protection layer BPL is a surface opposite to the surface facing the display panel DP and may be a surface that is not in contact with the display panel DP. Hereinafter, the expression “one surface is flat” may mean that the surface (e.g., the first surface S1) of the display panel DP, on which the one flat surface is disposed, and the one flat surface are substantially parallel to each other. For example, the expression “one surface is flat” mean that an angle is not formed with a surface (e.g., the first surface S1) of the display panel DP on which the one surface is disposed.

The bending protection layer BPL may have an approximately uniform thickness. In an embodiment, for example, the bending protection layer BPL may have a uniform thickness over the first area 1A, the bending area BA, and the second area 2A. The thickness of the bending protection layer BPL may be defined along a direction perpendicular to the plane on which the display panel DP is disposed, for example, along the third direction DR3. In accordance with an embodiment, the bending protection layer BPL may have a thickness in a range of about 30 micrometers (μm) to about 120 μm. In accordance with an embodiment, the bending protection layer BPL may have a thickness in a range of about 30 μm to about 90 μm. In accordance with an embodiment, the bending protection layer BPL may have a thickness in a range of about 60 μm to about 120 μm.

The bending protection layer BPL may include a curable material. In an embodiment, for example, the bending protection layer BPL may include at least one selected from a thermosetting material and a photocurable material. In an embodiment, for example, the bending protection layer BPL may include an ultraviolet curable resin as the photocurable material. In an embodiment, for example, the bending protection layer BPL may include at least one selected from epoxy acrylate resin, polyester acrylate resin, urethane acrylate resin, polyether acrylate resin, silicon acrylate resin, and alkyl acrylate resin as the photocurable material. In an embodiment, for example, the bending protection layer BPL may include at least one selected from epoxy resin, phenol resin, urea resin, melamine resin, and polyurethane resin as the thermosetting material. However, the disclosure is not limited thereto, and the bending protection layer BPL may include various curable materials.

The bending protection layer BPL in accordance with an embodiment may be formed by applying a resin on the display panel DP and then pressing the resin with a pressing part (see PT of FIG. 11) having one flat surface (e.g., the bottom surface). In such an embodiment, the bending protection layer BPL may have a flat top surface, and even when a dead space is reduced, the adhesion between the bending protection layer BPL and the display panel DP is increased, and thus, the risk that the bending protection layer BPL is to be peeled off from the display panel DP may be reduced.

In an embodiment, for example, where the dead space of the display device DD is reduced, a distance 10 from the end portion of the polarizing layer POL to the boundary between the first area 1A and the bending area BA is reduced. Accordingly, in a region from the end portion of the polarizing layer POL to the boundary between the first area 1A and the bending area BA, the contact area between the bending protection layer BPL and the display panel DP may be reduced. In such an embodiment where the contact area between the bending protection layer BPL and the display panel DP decreases, there is a risk that the bending protection layer BPL may be peeled off from the display panel DP. In an embodiment of the display device DD in accordance with the disclosure, the adhesion between the bending protection layer BPL and the display panel DP may be increased, thereby reducing the risk that the bending protection layer BPL is to be peeled off from the display panel DP. As a result, even when the dead space is reduced, the risk that the bending protection layer BPL is to be peeled off from the display panel DP may be reduced.

The support layer PL may not be disposed in the bending area BA. In an embodiment, for example, in a plan view, the support layer PL may not overlap the bending area BA. In a plan view, the support layer PL may not overlap at least a portion of the bending protection layer BPL. In an embodiment, for example, in a plan view, the support layer PL may not overlap at least a portion of the bending protection layer BPL disposed in the bending area BA.

FIG. 5 is a schematic cross-sectional view of a display device taken along line B-B′ of FIG. 1 in accordance with another embodiment. FIG. 5 illustrates an embodiment before a display device DD′ is bent in the bending area BA. The display device DD′ of FIG. 5 is substantially the same as the display device DD of FIG. 4, except that the bending protection layer BPL′ has a non-uniform thickness in some regions. Any repetitive detailed description of the same or like elements as those described above will be omitted or simplified.

In an embodiment, as shown in FIG. 5, the bending protection layer BPL′ may include a first portion P1 and a second portion P2. The first portion P1 may be disposed closer to the polarizing layer POL than the second portion P2. In an embodiment, for example, the first portion P1 may be in contact with the polarizing layer POL, and the second portion P2 may be not in contact with the polarizing layer POL.

The first portion P1 may have a non-uniform thickness. The first portion P1 may have an inclined top surface. In an embodiment, for example, the first portion P1 may have a thickness that decreases as the distance from the polarizing layer POL increases.

The second portion P2 may have an approximately uniform thickness. The second portion P2 may have an approximately flat top surface. An average thickness of the second portion P2 may be less than an average thickness of the first portion P1.

Each of the first portion P1 and the second portion P2 may have an average thickness in a range of about 30 μm to about 120 μm. In accordance with an embodiment, each of the first portion P1 and the second portion P2 may have an average thickness in a range of about 30 μm to about 90 μm. In accordance with an embodiment, each of the first portion P1 and the second portion P2 may have an average thickness in a range of 6 about 0 μm to about 120 μm.

The bending protection layer BPL′ in accordance with an embodiment may be formed by applying a resin on the display panel DP and then pressing the resin in a partial region with a pressing part (see PT′ of FIG. 16) having one inclined surface (e.g., the bottom surface). Accordingly, the bending protection layer BPL′ may have a greater average thickness in the first portion P1 than in the second portion P2, and the area of the bending protection layer BPL′ in contact with the polarizing layer POL increases. The adhesion between the bending protection layer BPL′ and the polarizing layer POL is increases, and thus, the bending protection layer BPL′ may be more firmly bonded to the display panel DP and the risk that the bending protection layer BPL′ is to be peeled off from the display panel DP may be reduced.

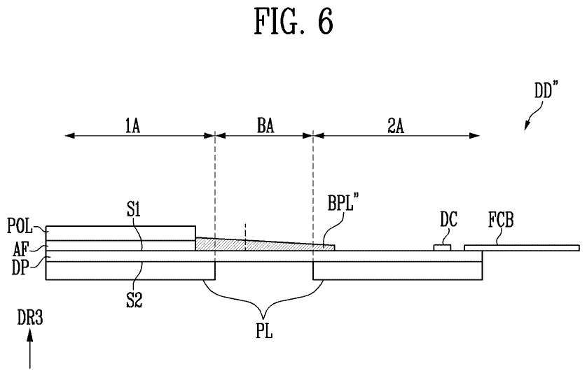

FIG. 6 is a schematic cross-sectional view of a display device taken along line B-B′ of FIG. 1 in accordance with another embodiment. FIG. 6 illustrates an embodiment before a display device DD″ is bent in the bending area BA. The display device DD″ of FIG. 6 is substantially the same as the display device DD of FIOG. 4, except that a bending protection layer BPL″ has a non-uniform thickness. Any repetitive detailed description of the same or like elements as those described above will be omitted or simplified.

In an embodiment, as shown in FIG. 6, the bending protection layer BPL″ may have an inclined top surface. The bending protection layer BPL″ may not have a flat top surface. In an embodiment, for example, the bending protection layer BPL″ may have a thickness that decreases as the distance from the polarizing layer POL increases. In an embodiment, for example, the bending protection layer BPL″ may have a thickness that decreases from the end portion that is in contact with the polarizing layer POL to the end portion that is not in contact with the polarizing layer POL.

The bending protection layer BPL″ may have an average thickness in a range of about 30 μm to about 120 μm. In accordance with an embodiment, the bending protection layer BPL″ may have an average thickness in a range of about 30 μm to about 90 μm. In accordance with an embodiment, the bending protection layer BPL″ may have an average thickness in a range of about 60 μm to about 120 μm.

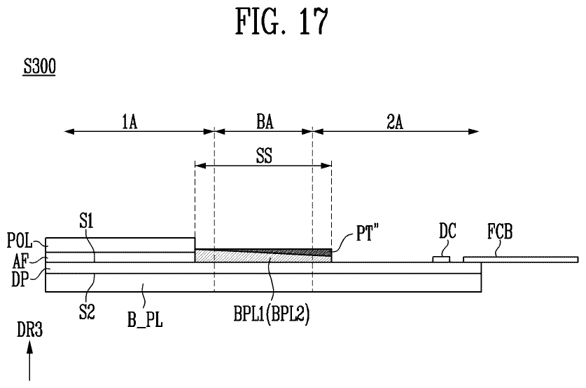

The bending protection layer BPL″ in accordance with an embodiment may be formed by applying a resin on the display panel DP and then pressing the resin with a pressing part (see PT″ of FIG. 17) having one inclined surface (e.g., the bottom surface). Accordingly, the contact area between the bending protection layer BPL″ and the polarizing layer POL may be increased. Accordingly, the adhesion between the bending protection layer BPL″ and the polarizing layer POL may be increased, thereby reducing the risk that the bending protection layer BPL″ is to be peeled off from the display panel DP.

In embodiments, the shape of the bending protection layer BPL may variously vary depending on the shape of the pressing part PT. In such embodiments, the average thickness of the bending protection layer BPL may be in a range of about 30 μm to about 120 μm, and as the bending protection layer BPL has the above-described thickness, bending stress may be reduced when the display device DD is bent.

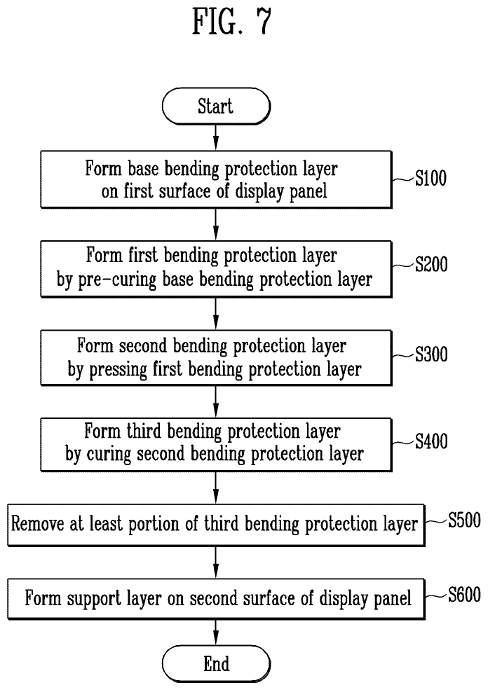

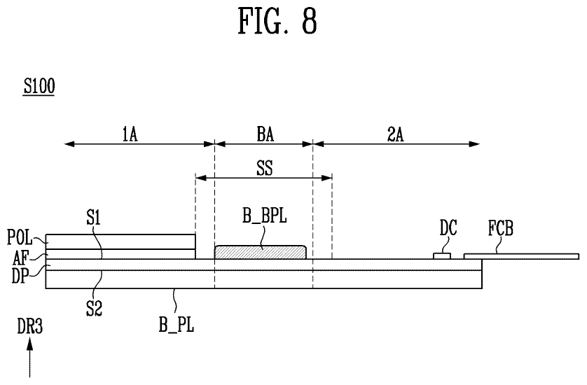

Hereinafter, an embodiment of a method of manufacturing the display device DD will be described with reference to FIGS. 7 to 15. FIG. 7 is a schematic flowchart of a method of manufacturing a display device in accordance with an embodiment. FIGS. 8 to 15 are schematic diagrams of processes in an embodiments of the method of manufacturing the display device of FIG. 4. Some drawings of FIGS. 8 to 15 are schematic cross-sections of processes of the method of manufacturing the display device in accordance with an embodiment, and the remaining drawings are schematic plan views of processes according to the method of manufacturing the display device in accordance with an embodiment. In FIGS. 8 to 15, the same or like elements as those described above are labeled with the same or like reference characters as used above and any repetitive detailed description thereof will hereinafter be omitted or simplified.

Referring to FIG. 7, an embodiment of the method of manufacturing the display device DD may include forming a base bending protection layer on a first surface of a display panel (S100), forming a first bending protection layer by pre-curing the base bending protection layer (S200), forming a second bending protection layer by pressing the first bending protection layer (S300), forming a third bending protection layer by curing the second bending protection layer (S400), removing at least a portion of the third bending protection layer (S500), and forming a support layer on a second surface of the display panel (S600).

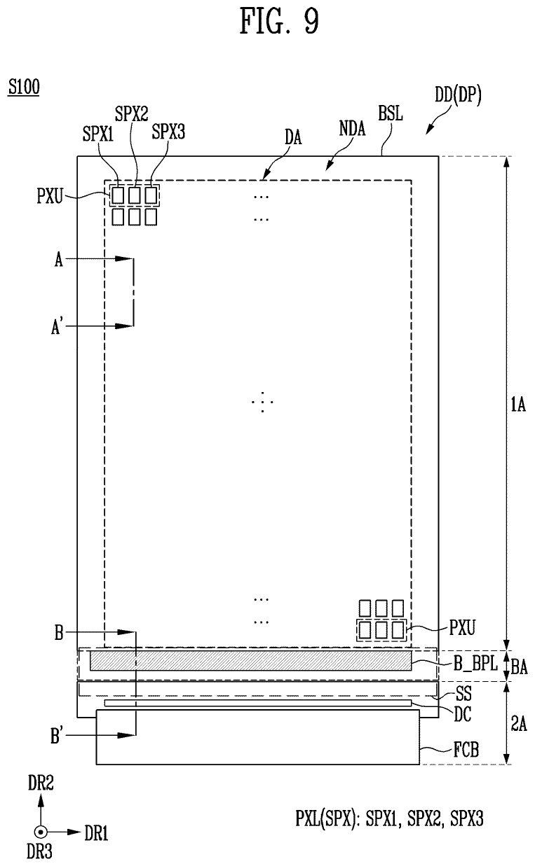

Referring to FIGS. 8 and 9, before the forming of the base bending protection layer on the first surface of the display panel (S100), a display panel having a first area 1A, a second area 2A spaced apart from the first area 1A in a second direction DR2, and a bending area BA located between the first area 1A and the second area 2A may be formed or prepared. In an embodiment, the method of manufacturing the display device DD may include forming the display panel DP and forming an adhesive layer AF, a polarizing layer POL, and a base support layer B_PL. The forming of the adhesive layer AF, the polarizing layer POL, and the base support layer B_PL may be performed after the forming of the display panel DP. The adhesive layer AF and the polarizing layer POL may be formed in the first area 1A on the first surface S1 of the display panel DP. A driving circuit chip DC and a flexible circuit board FCB may be formed or provided in the second area 2A on the first surface S1 of the display panel DP. The base support layer B_PL may be formed on the second surface S2 of the display panel DP.

The forming of the base support layer B_PL on the second surface S2 of the display panel DP may include forming the base support layer B_PL to cover the entire second surface S2 of the display panel DP. The forming of the base support layer B_PL may include forming the base support layer B_PL to be entirely in contact with the second surface S2 of the display panel DP. In a plan view (or when viewed in the third direction DR3), the base support layer B_PL may overlap the first area 1A, the second area 2A, and the bending area BA.

The forming of the base bending protection layer on the first surface of the display panel (S100) may include applying a resin on the first surface S1 of the display panel DP. The forming of the base bending protection layer on the first surface of the display panel (S100) may include applying a resin in a way such that the base bending protection layer B_BPL overlaps the base support layer B_PL in the bending area BA in a plan view. The resin may be applied directly on the display panel DP, and the resin applied on the first surface S1 of the display panel DP may form the base bending protection layer B_BPL.

The resin may include a curable material. In an embodiment, for example, the resin may include at least one selected from a thermosetting material and a photocurable material. In an embodiment, for example, the resin may include an ultraviolet curable resin as the photocurable material. In an embodiment, for example, the resin may include at least one selected from epoxy acrylate resin, polyester acrylate resin, urethane acrylate resin, polyether acrylate resin, silicon acrylate resin, and alkyl acrylate resin as the photocurable material. In an embodiment, for example, the resin may include at least one selected from epoxy resin, phenol resin, urea resin, melamine resin, and polyurethane resin as the thermosetting material. However, the disclosure is not limited thereto, and the resin may include various curable materials.

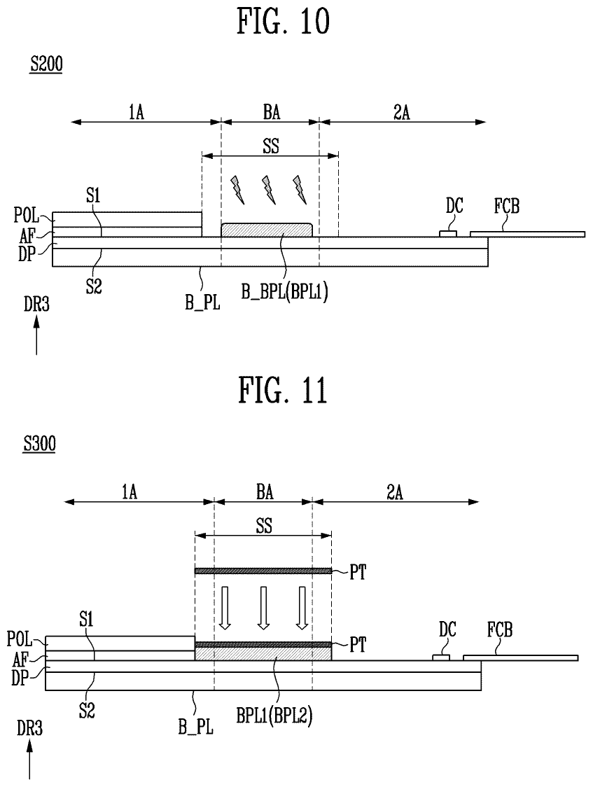

The resin (or the base bending protection layer B_BPL) may form the bending protection layer BPL through a pre-curing process, a pressing process, and a curing process. This is described below in greater detail with reference to FIGS. 10 to 13.

The resin may be applied within a bending protection layer formation area SS. The bending protection layer formation area SS is an area where the bending protection layer BPL is formed on the display panel DP when the display device DD is manufactured, and may be an area where the bending protection layer BPL and the display panel DP are in contact with each other. In an embodiment, for example, the bending protection layer formation area SS may be an area where the bending protection layer BPL and the display panel DP overlap each other in a plan view. The bending protection layer formation area SS may change depending on the product design of the display device DD.

The resin application area (or the area of the bottom surface of the base bending protection layer B_BPL) may be smaller than the area of the bending protection layer formation area SS. The resin application area (or the area of the bottom surface of the base bending protection layer B_BPL) may be smaller than the area of the bending area BA. In an embodiment, for example, the contact area between the base bending protection layer B_BPL and the display panel DP may be smaller than the contact area between the bending protection layer BPL and the display panel DP. In an embodiment, for example, the contact area between the resin and the display panel DP (or the area of the bottom surface of the base bending protection layer B_BPL) may be smaller than the area where the bending protection layer formation area SS and the display panel DP overlap each other in a plan view.

The resin may be applied in a way such that the shape of the base bending protection layer B_BPL corresponds to the shape of the display panel DP in the bending area BA. In an embodiment, for example, the base bending protection layer B_BPL may have a same shape as the display panel DP in the bending area BA. In an embodiment, for example, where the display panel DP in the bending area BA has a rectangular shape, the base bending protection layer B_BPL may have a rectangular shape. In an embodiment, for example, where the display panel DP in the bending area BA has a trapezoidal shape, the base bending protection layer B_BPL may have a trapezoidal shape.

Referring to FIG. 10, the forming of the first bending protection layer by pre-curing the base bending protection layer (S200) may include pre-curing the base bending protection layer B_BPL.

The forming of the first bending protection layer by pre-curing the base bending protection layer (S200) may include exposing the base bending protection layer B_BPL to heat or ultraviolet rays for less than about 3 minutes. When the resin includes a thermosetting material, the base bending protection layer B_BPL may be cured by heat. In accordance with an embodiment, when the resin includes a thermosetting material, the base bending protection layer B_BPL may be exposed to heat for less than about 3 minutes. When the resin includes a photocurable material, the base bending protection layer B_BPL may be cured by ultraviolet rays. In accordance with an embodiment, when the resin includes a photocurable material, the base bending protection layer B_BPL may be exposed to ultraviolet rays for less than about 3 minutes.

In the forming of the first bending protection layer by pre-curing the base bending protection layer (S200), at least a portion of the base bending protection layer B_BPL may be cured. In an embodiment, for example, the surface of the base bending protection layer B_BPL may be cured, and at least a portion of the interior of the base bending protection layer B_BPL may not be cured.

The base bending protection layer B_BPL may be pre-cured to form a first bending protection layer BPL1. The first bending protection layer BPL1 may refer to the base bending protection layer B_BPL that has undergone the pre-curing process. As the base bending protection layer B_BPL undergoes the pre-curing process, the surface of the base bending protection layer B_BPL may be cured, and even when the first bending protection layer BPL1 is then pressed with the pressing part PT, the resin may not be attached to the pressing part PT.

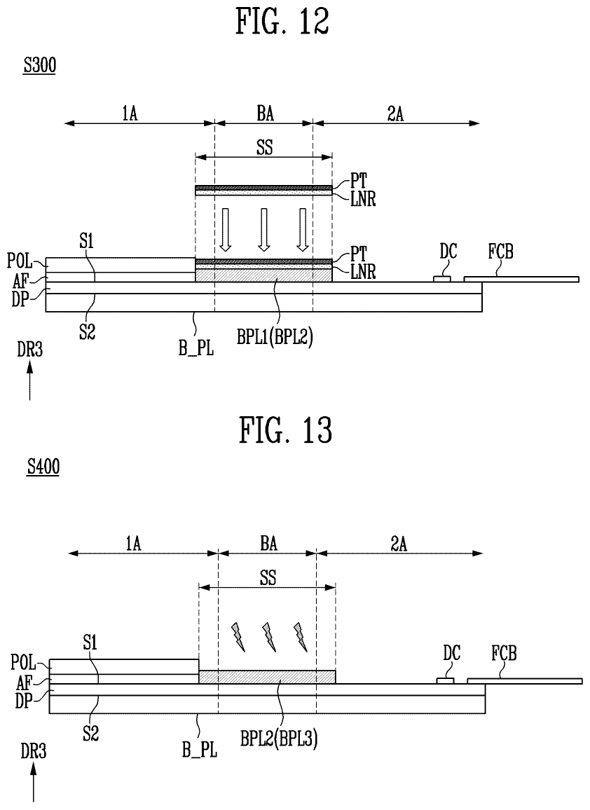

Referring to FIGS. 11 and 12, the forming of the second bending protection layer by pressing the first bending protection layer (S300) may include pressing the first bending protection layer BPL1 with the pressing part PT.

The pressing part PT may have an approximately flat surface. In an embodiment, for example, the pressing part PT may have an approximately flat bottom surface. The bottom surface of the pressing part PT may be a surface facing the first bending protection layer BPL1.

The pressing part PT may press the first bending protection layer BPL1. The pressing part PT may press the first bending protection layer BPL1, and the first bending protection layer BPL1 may be pressed to form a second bending protection layer BPL2. The second bending protection layer BPL2 may refer to the first bending protection layer BPL1 that has undergone the pressing process.

The first bending protection layer BPL1 may be pressed to have a thickness in a range of about 30 μm to about 120 μm. The first bending protection layer BPL1 may be pressed to have a thickness in a range of about 30 μm to about 90 μm. The first bending protection layer BPL1 may be pressed to have a thickness in a range of about 60 μm to about 120 μm. As the first bending protection layer BPL1 is pressed, the first bending protection layer BPL1 may have a thickness of about 120 μm or less.

In accordance with an embodiment (see FIG. 11), the pressing part PT and the first bending protection layer BPL1 may be in contact with each other. However, the disclosure is not limited thereto. In accordance with an embodiment (see FIG. 12), a liner LNR may be further disposed below the pressing part PT, and the liner LNR and the first bending protection layer BPL1 may be in contact with each other.

The liner LNR may be a film layer. The liner LNR may be previously attached to the pressing part PT, and when the pressing part PT presses the first bending protection layer BPL1, the liner LNR may be disposed between the pressing part PT and the first bending protection layer BPL1. The liner LNR may include at least one selected from polyethylene terephthalate (PET), polycarbonate (PC), and polyimide (PI). However, the disclosure is not limited thereto, and the liner LNR may include various materials known as release film materials. The liner LNR may effectively prevent the resin from being attached to the pressing part PT when the base bending protection layer B_BPL is not properly cured. The liner LNR may be removed after the pressing process has been performed.

The top surface of the second bending protection layer BPL2 may have a shape corresponding to the bottom surface of the pressing part PT (or the bottom surface of the liner LNR). In an embodiment, for example, when the bottom surface of the pressing part PT (or the bottom surface of the liner LNR) is flat, the top surface of the second bending protection layer BPL2 may be flat. In an embodiment, for example, the slope of the top surface of the second bending protection layer BPL2 may be substantially the same as the slope of the bottom surface of the pressing part PT (or the bottom surface of the liner LNR).

The forming of the second bending protection layer by pressing the first bending protection layer (S300) may include, when the pressing part PT presses the first bending protection layer BPL1, bringing the base support layer B_PL into contact with the display panel DP as a whole. In an embodiment, for example, when the pressing part PT presses the first bending protection layer BPL1, the base support layer B_PL is not peeled off from the display panel DP and may overlap the bending area BA of the display panel DP in a plan view. When the pressing part PT presses the first bending protection layer BPL1, the first bending protection layer BPL1 may overlap the base support layer B_PL in a plan view. Accordingly, when the pressing part PT presses the first bending protection layer BPL1, the base support layer B_PL may support the lower portion of the display panel DP, and the adhesion to the display panel DP may be increased when the first bending protection layer BPL1 is pressed.

The first bending protection layer BPL1 may be pressed to form the second bending protection layer BPL2, and the contact area between the second bending protection layer BPL2 and the display panel DP may be larger than the contact area between the base bending protection layer B_BPL and the display panel DP. The contact area between the second bending protection layer BPL2 and the display panel DP may be larger than the area of the bending protection layer formation area SS. In an embodiment, for example, the contact area between the second bending protection layer BPL2 and the display panel DP may be larger than the area of the region where the bending protection layer formation area SS overlaps the display panel DP in a plan view.

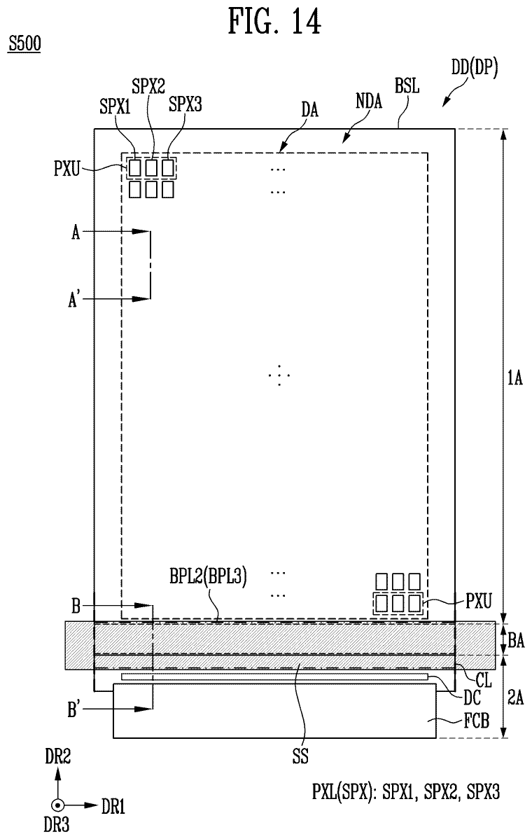

The second bending protection layer BPL2 may be formed by pressing and may also be formed in a region outside the bending protection layer formation area SS in a plan view (see FIG. 14). In an embodiment, for example, in a plan view, at least a portion of the second bending protection layer BPL2 may be formed in a region outside a region where the display panel DP is disposed. In an embodiment, for example, in a plan view, at least a portion of the second bending protection layer BPL2 may not overlap the display panel DP.

Referring to FIG. 13, the forming of the third bending protection layer by curing the second bending protection layer (S400) may include curing the second bending protection layer BPL2. The second bending protection layer BPL2 may be cured for a longer time than the pre-curing time of the base bending protection layer B_BPL.

The forming of the third bending protection layer by curing the second bending protection layer (S400) may include exposing the second bending protection layer BPL2 to heat or ultraviolet rays for less than about 5 minutes. In an embodiment, for example, where the resin includes a thermosetting material, the second bending protection layer BPL2 may be cured by heat. In such an embodiment, where the resin includes a thermosetting material, the second bending protection layer BPL2 may be exposed to heat for less than about 5 minutes. In an embodiment, for example, where the resin includes a photocurable material, the second bending protection layer BPL2 may be cured by ultraviolet rays. In such an embodiment, where the resin includes a photocurable material, the second bending protection layer BPL2 may be exposed to ultraviolet rays for less than about 5 minutes.

In the forming of the third bending protection layer by curing the second bending protection layer (S400), the uncured second bending protection layer BPL2 may be cured. In an embodiment, for example, at least a portion of the second bending protection layer BPL2 that is not cured in the pre-curing process may be cured.

The second bending protection layer BPL2 may be cured to form a third bending protection layer BPL3. The third bending protection layer BPL3 may refer to the second bending protection layer BPL2 that has undergone the curing process.

Referring to FIG. 14, in the removing of at least a portion of the third bending protection layer S500, at least a portion of the third bending protection layer BPL3 disposed outside the bending protection layer formation area SS (or outside the region where the display panel DP is disposed) may be cut along a cutting line CL. The removing of at least a portion of the third bending protection layer (S500) may include removing at least a portion of the third bending protection layer BPL3 disposed outside the bending protection layer formation area SS by performing cutting thereon along the cutting line CL, and may include forming the bending protection layer BPL with the remaining portion of the third bending protection layer BPL3 that has not been removed.

When the first bending protection layer BPL1 is pressed to form the second bending protection layer BPL2, the second bending protection layer BPL2 may also be formed outside the bending protection layer formation area SS. The third bending protection layer BPL3 formed by curing the second bending protection layer BPL2 may also be formed outside the bending protection layer formation area SS. In an embodiment, for example, in a plan view, the third bending protection layer BPL3 may also be formed in a region outside the region where the display panel DP is disposed. In an embodiment, for example, in a plan view, at least a portion of the third bending protection layer BPL3 may not overlap the region where the display panel DP is disposed.

In the removing of at least a portion of the third bending protection layer (S500), at least a portion of the third bending protection layer BPL3 disposed outside the bending protection layer formation area SS may be cut along the cutting line CL and the bending protection layer BPL may be formed. In an embodiment, for example, in a plan view, at least a portion of the third bending protection layer BPL3 disposed in the region outside the region where the display panel DP is disposed may be cut along the cutting line CL and the bending protection layer BPL may be formed.

The cutting line CL may coincide with the boundary of the bending protection layer formation area SS. In an embodiment, for example, in a plan view, the cutting line CL may overlap side edges of the bending protection layer BPL. In an embodiment, for example, the cutting line CL may overlap corners (or edges) of the display panel DP. Referring to FIG. 1, at least a portion of the third bending protection layer BPL3 may be cut and removed along the cutting line CL, and the remaining portion of the third bending protection layer BPL3 (or the bending protection layer BPL3) that is not removed and remains on the display panel DP may completely overlap the display panel DP in a plan view.

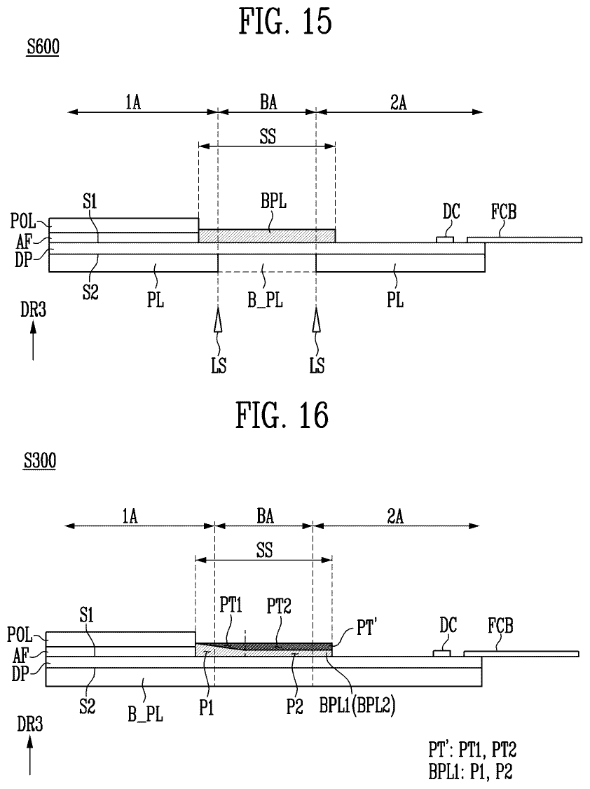

Referring to FIG. 15, the forming of the support layer on the second surface of the display panel (S600) may include radiating a laser LS onto the base support layer B_PL and removing at least a portion of the base support layer B_PL.

In the radiating of the laser LS onto the base support layer B_PL, the laser LS may be radiated onto one region of the base support layer B_PL. In an embodiment, for example, the laser LS may be radiated onto a region of the base support layer B_PL that overlaps the boundary between the bending area BA and the second area 2A and the boundary between the bending area BA and the first area 1A. However, the disclosure is not limited thereto. In accordance with an embodiment, the laser LS may be radiated onto a region of the base support layer B_PL that overlaps the second area 2A and the first area 1A in a plan view.

The laser LS may be at least one of a CO₂ laser, an yttrium aluminum garnet (YAG) laser, a nano second laser, a femto second laser, a Bessel beam, and a Gaussian beam.

The laser LS may be radiated onto the base support layer B_PL, and thus, the base support layer B_PL may be half-cut. In an embodiment, for example, the laser LS may be radiated onto the base support layer B_PL to form a cut portion in the base support layer B_PL, and the depth of the cut portion may be less than ½ of the thickness of the base support layer B_PL. In accordance with an embodiment, the depth of the cut portion may be less than ⅓ of the thickness of the base support layer B_PL.

In the removing of at least a portion of the base support layer B_PL, the base support layer B_PL irradiated with the laser LS may be peeled off (or removed). The base support layer B_PL overlapping the bending area BA may be peeled off (or removed) from the display panel DP. At least a portion of the base support layer B_PL may be peeled off (or removed), and the remaining portion thereof that has not been peeled off may exist in the first area 1A and the second area 2A. The base support layer B_PL may be partially peeled off to form the support layer PL disposed in the first area 1A and the second area 2A.

In embodiments of the method of manufacturing the display device DD in accordance with the disclosure, the base bending protection layer B_BPL, the first bending protection layer BPL1, the second bending protection layer BPL2, and the third bending protection layer BPL3 may be formed before the removing of at least a portion of the support layer B_PL. The bending protection layer BPL may be formed before the support layer PL is formed. The base support layer B_PL may support the display panel DP and the bending protection layer BPL is formed on the base support layer B_PL by pressing, the adhesion between the bending protection layer BPL and the display panel DP may be increased.

After the support layer PL is formed, the display device DD may be bent along the bending area BA. The adhesion between the bending protection layer BPL and the display panel DP is increased. Accordingly, even when the display device DD is bent, the risk that the bending protection layer BPL is to be peeled off from the display panel DP may be reduced, and the defects of the display device DD may be reduced.

Hereinafter, other embodiments of a method of manufacturing the display devices DD will be described with reference to FIGS. 16 and 17. FIG. 16 is a schematic diagram of a process in an embodiment of a method of manufacturing the display device of FIG. 5. FIG. 17 is a schematic diagram of a process in an embodiment of a method of manufacturing the display device of FIG. 6. Descriptions redundant with those provided above are omitted.

Referring to FIG. 16, in accordance with an embodiment, a pressing part PT′ may have an inclined surface in a partial region thereof. In an embodiment, for example, the pressing part PT′ may include a first pressing part PT1 having an inclined surface and a second pressing part PT2 having an approximately flat surface. One surface of the pressing part PT′ may be a surface facing the first bending protection layer BPL1 and may be a bottom surface of the pressing part PT′. The bottom surface of the first pressing part PT1 may be an inclined surface, and the bottom surface of the second pressing part PT2 may be an approximately flat surface.

The pressing part PT′ may press a first bending protection layer BPL1. The pressing part PT′ may press the first bending protection layer BPL1, and the first bending protection layer BPL1 may be pressed to form a second bending protection layer BPL2 having a first portion P1 and a second portion P2. The second bending protection layer BPL2 may refer to the first bending protection layer BPL1 that has undergone the pressing process.

The top surface of the second bending protection layer BPL2 may have a shape corresponding to the bottom surface of the pressing part PT′. In an embodiment, for example, the slope of the top surface of the second bending protection layer BPL2 may be substantially the same as the slope of the bottom surface of the pressing part PT′. In an embodiment, for example, the slope of the first portion P1 of the first bending protection layer BPL1 and the slope of the first pressing part PT1 of the pressing part PT′ may be the same as each other. In an embodiment, for example, where the bottom surface of the first pressing part PT1 of the pressing part PT′ is inclined, the top surface of the first portion P1 of the first bending protection layer BPL1 may be inclined. In an embodiment, for example, where the second pressing part PT2 of the pressing part PT′ has a flat bottom surface, the second portion P2 of the first bending protection layer BPL1 may have a flat bottom surface.

In accordance with an embodiment, although not illustrated in FIG. 16, in the method of manufacturing the display device DD′ in accordance with an embodiment, a liner LNR may be further disposed below the pressing part PT′.

In the method of manufacturing the display device DD′ in accordance with an embodiment, as the pressing part PT′ includes one inclined surface, the area of the second bending protection layer BPL2 in contact with the polarizing layer POL may be increased. Accordingly, the adhesion between the second bending protection layer BPL2 and the polarizing layer POL may be increased, thereby reducing the risk that the bending protection layer BPL is to be peeled off from the display panel DP when the bending protection layer BPL is formed.

Referring to FIG. 17, in accordance with an embodiment, a pressing part PT″ may have one inclined surface. One surface of the pressing part PT″ may be a surface facing the first bending protection layer BPL1 and may be a bottom surface of the pressing part PT″. The bottom surface of the pressing part PT″ may not be flat.

The top surface of the second bending protection layer BPL2 may have a shape corresponding to the bottom surface of the pressing part PT″. In an embodiment, for example, the slope of the top surface of the second bending protection layer BPL2″ may be substantially the same as the slope of the bottom surface of the pressing part PT″. In an embodiment, for example, when the bottom surface of the pressing part PT″ is inclined, the top surface of the first bending protection layer BPL1 may be inclined and may have the same inclination as the pressing part PT″.

In accordance with an embodiment, although not illustrated in FIG. 17, in the method of manufacturing the display device DD″ in accordance with an embodiment, a liner LNR may be further disposed below the pressing part PT″.

In the method of manufacturing the display device DD″ in accordance with an embodiment, as the pressing part PT″ includes one inclined surface, the area of the second bending protection layer BPL2 in contact with the polarizing layer POL may be increased. Accordingly, the adhesion between the second bending protection layer BPL2 and the polarizing layer POL may be increased, thereby reducing the risk that the bending protection layer BPL is to be peeled off from the display panel DP when the bending protection layer BPL is formed.

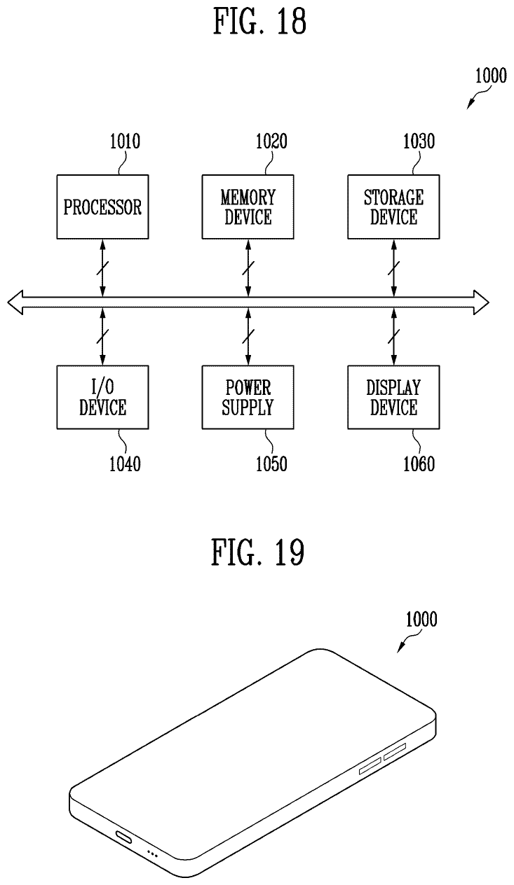

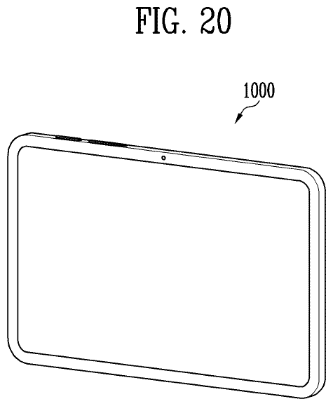

FIG. 18 is a schematic block diagram illustrating an electronic device 1000 including a display device in accordance with an embodiment. FIG. 19 is a schematic diagram illustrating an example where the electronic device 1000 of FIG. 18 is a smartphone. FIG. 20 is a schematic diagram illustrating an example where the electronic device 1000 of FIG. 18 is a tablet computer.

Referring to FIGS. 18 to 20, the electronic device 1000 may include a processor 1010, a memory device 1020, a storage device 1030, an input/output (I/O) device 1040, a power supply 1050, and a display device 1060. The display device 1060 may be the display device DD, DD′, DD″ of FIGS. 1, 4, 5, and 6. The electronic device 1000 may further include various ports for communication with a video card, a sound card, a memory card, a USB device, or other systems. In an embodiment, as illustrated in FIG. 19, the electronic device 1000 may be a smartphone. In an embodiment, as illustrated in FIG. 20, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

In accordance with embodiment of the disclosure, a display device capable of reducing dead space and a defect rate and a method of manufacturing the display device may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of manufacturing a display device, the method comprising:
forming a display panel including a first area, a second area spaced apart from the first area in a first direction, and a bending area located between the first area and the second area, wherein the display panel includes a first surface and a second surface, which are opposite to each other;
forming a base bending protection layer on the first surface of the display panel;
forming a base support layer on the second surface of the display panel;
forming a first bending protection layer by pre-curing the base bending protection layer;
forming a second bending protection layer by pressing the first bending protection layer; and
removing at least a portion of the base support layer,
wherein the base bending protection layer is formed before the removing the at least a portion of the base support layer.

2. The method of claim 1, wherein the forming the base support layer comprises forming the base support layer to be in contact with the second surface of the display panel.

3. The method of claim 1, wherein the forming the base bending protection layer comprises the forming the base bending protection layer to overlap the base support layer in a plan view.

4. The method of claim 1, wherein the forming the second bending protection layer comprises pressing the first bending protection layer with a pressing part, and
the pressing part has a flat bottom surface which is substantially parallel to the first surface.

5. The method of claim 1, wherein the forming the second bending protection layer comprises pressing the first bending protection layer with a pressing part,
the pressing part comprises a first pressing part and a second pressing part,
a bottom surface of the first pressing part is an inclined surface with respect to the first surface, and
a bottom surface of the second pressing part is a flat surface which is substantially parallel to the first surface.

6. The method of claim 1, wherein the forming the second bending protection layer comprises pressing the first bending protection layer with a pressing part, and
a bottom surface of the pressing part is not flat.

7. The method of claim 1, wherein the forming the second bending protection layer comprises pressing the first bending protection layer disposed to overlap the base support layer in a plan view.

8. The method of claim 1, wherein the forming the second bending protection layer comprises pressing the first bending protection layer with a pressing part,
wherein a liner is disposed below the pressing part in way such that, the liner is disposed between the first bending protection layer and the pressing part when the pressing part presses the first bending protection layer, and
wherein the liner is a film.

9. The method of claim 1, wherein the forming the base bending protection layer on the first surface of the display panel comprises applying a resin to have an area smaller than the bending area, and
the resin comprises a photocurable material or a thermosetting material.

10. The method of claim 1, further comprising forming a third bending protection layer by curing the second bending protection layer,
wherein at least a portion of the third bending protection layer is formed in a region outside a region where the display panel is disposed.

11. The method of claim 10, further comprising removing the at least a portion of the third bending protection layer,
wherein the removing the at least a portion of the third bending protection layer comprises cutting the third bending protection layer formed in the region outside the region where the display panel is disposed.

12. The method of claim 10, wherein a bending protection layer is defined by a remaining portion of the third bending protection layer which remains after the removing the at least a portion of the third bending protection layer, and
a contact area between the display panel and the base bending protection layer is smaller than a contact area between the display panel and the bending protection layer.

13. The method of claim 12, wherein the bending protection layer has a same shape as the display panel in the bending area.

14. The method of claim 10, wherein the forming the third bending protection layer comprises exposing the second bending protection layer to heat or ultraviolet rays for less than about 5 minutes, and
the forming the first bending protection layer comprises exposing the base bending protection layer to the heat or the ultraviolet rays for less than about 3 minutes.

15. The method of claim 1, wherein the removing the at least a portion of the base support layer comprises radiating a laser onto one region of the base support layer,
the laser is at least one selected from a CO₂ laser, a YAG laser, a nano second laser, a femto second laser, a Bessel beam, and a Gaussian beam, and
the at least a portion of the base support layer to be removed is a portion of the base support layer which overlaps the bending area in a plan view.

16. A display device comprising:
a display panel comprising a first area, a second area spaced apart from the first area in a first direction, and a bending area located between the first area and the second area, wherein the display panel includes a first surface and a second surface, which are opposite to each other;
a bending protection layer disposed in the bending area on the first surface of the display panel; and
a support layer disposed in the first area and the second area on the second surface of the display panel,
wherein the bending protection layer has a thickness in a range of about 30 μm to about 120 μm, and
the support layer does not overlap the bending area in a plan view.

17. The display device of claim 16, wherein the bending protection layer has a flat top surface which is substantially parallel to the first surface, and
the top surface of the bending protection layer is a surface opposite to a surface of the bending protection layer facing the display panel.

18. The display device of claim 16, further comprising a polarizing layer disposed in the first area on the first surface of the display panel,
wherein the bending protection layer includes a first portion and a second portion,
the first portion has a thickness which decreases as a distance from the polarizing layer increases, and
the second portion has a uniform thickness.

19. The display device of claim 16, further comprising a polarizing layer disposed in the first area on the first surface of the display panel,
wherein the bending protection layer has a thickness which decreases as a distance from the polarizing layer increases, and
wherein the bending protection layer has a same shape as the display panel in the bending area.

20. An electronic device, comprising:
a processor to provide input image data; and
a display device to display an image based on the input image data,
wherein the display device comprises:
a display panel comprising a first area, a second area spaced apart from the first area in a first direction, and a bending area located between the first area and the second area, wherein the display panel includes a first surface and a second surface, which are opposite to each other;
a bending protection layer disposed in the bending area on the first surface of the display panel; and
a support layer disposed in the first area and the second area on the second surface of the display panel,
wherein the bending protection layer has a thickness in a range of about 30 μm to about 120 μm, and
the support layer does not overlap the bending area in a plan view.
